(19) United States
(12) Patent Application Publication
(10) Pub. No.: US 2002/0050866 A1
(43) Pub. Date: May 2, 2002

(54) Voltage controlled oscillator and communication device using the same

(75) Inventor: Hirofumi Aki, Kaga-shi (JP)

Correspondence Address: Keating & Bennett LLP, Suite 312, 10400 Eaton Place, Fairfax, VA, 22030, US

(73) Assignee: Murata Manufacturing Co., Ltd., Nagaokakyo-shi (JP)

(21) Appl. No.: 09/962,175

(22) Filed: Sep. 25, 2001

(30) Foreign Application Priority Data
Oct. 31, 2000 (JP) 2000-332565

(51) Int. Cl. H03B 5/18; H03B 7/12

(52) U.S. Cl. 331/100

(57) ABSTRACT

A voltage controlled oscillator changes two different frequencies to operate, and includes a resonance circuit, an oscillation circuit, and a buffer circuit. The resonance circuit includes a variable capacity diode, a diode which is a switching element, a strip line resonator, an inductor, a resistor, coupling capacitors, and a DC blocking capacitor. The intermediate tap CT1, which is located at a position other than the ends in the strip line resonator, of the strip line resonator is grounded via the diode as the switching element, and the DC blocking capacitor. The diode as the switching element is connected to a control terminal via the resistor.

### BACKGROUND OF THE INVENTION

1. Field of the Invention

The present invention relates to a voltage controlled oscillator and a communication device including the same, and more particularly, to a voltage controlled oscillator which changes a plurality of different frequencies during operation, and a communication device including such a voltage controlled oscillator.

2. Description of the Related Art

In recent years, plural communication systems using different frequencies have been widely used. With the increase usage of the systems, it has become more and more important that the plural communication systems can be accessed and used by a single communication device. In this case, a high frequency oscillation circuit such as a voltage controlled oscillator, which constitutes a local oscillation circuit of the communication device, needs to change its frequency to the plural different frequencies to operate within the many different communication systems.

FIG. 5 is a circuit diagram of a conventional voltage controlled oscillator. Japanese Unexamined Patent Application Publication No. 11-186844 discloses a voltage controlled oscillator 50 that changes between two different frequencies to operate and includes a resonance circuit 1, an oscillation circuit 2, and a buffer circuit 3.

The resonance circuit 1 selects one of the two different frequencies, and outputs a signal resonated at the selected frequency. The resonance circuit 1 includes a variable capacity diode VD1, a diode D1, a strip line resonator L1, an inductor L2, a resistor R1, coupling capacitors C1 and C2, and a DC blocking capacitor C3. The anode of the variable capacity diode VD1 is grounded, and the cathode is connected to a voltage-supply terminal 4 via the inductor L2. The node between the variable capacity diode VD1 and the inductor L2 is connected to the oscillation circuit 2 via the coupling capacitors C1 and C2. One terminal of the strip line resonator L1 is connected to the node between the coupling capacitors C1 and C2, and the other terminal is grounded. An intermediate tap CT, which is located at a position other than the terminals of the strip line resonator L1, of the strip line resonator L1 is connected to the anode of the diode D1 via the DC blocking capacitor C3, and the cathode of the diode D1 is grounded. Moreover, the node between the DE blocking capacitor C3 and the diode D1 is connected to a control terminal 5 via the resistor R1. The coupling capacitor C1 couples the variable capacity diode VD1 to the strip line resonator L1. The coupling capacitor C2 couples the strip line resonator L1 to the oscillation circuit 2.

The oscillation circuit 2 is a Colpitts oscillation circuit provided with a transistor Q1 and operated in a common-emitter mode. A capacitor C4 for generating a feedback capacity is connected between the base and the emitter of the transistor Q1. The emitter of the transistor Q1 is connected to the buffer circuit 3 via a capacitor C5, and also, is grounded via a capacitor C6. Moreover, the collector of the transistor Q1 is connected to a power-supply terminal 6 via an inductor L3 as a choke coil, and also, is grounded via a capacitor C7.

Referring to the voltage controlled oscillator 50 configured as described above, a signal resonated by the resonance circuit 1 is input to the base of the transistor Q1 in the oscillation circuit 2, and is oscillated by the transistor Q1. The oscillation signal is amplified by the buffer circuit 3 and is output via an output terminal 7. Two different frequencies can be changed and used for oscillation by controlling the on-off of the diode D1 using a voltage applied to the control terminal 5.

In particular, when no voltage is applied to the control terminal 5, the diode D1 is off, so that the DC blocking capacitor C3 and the diode D1 are electrically separated from the strip line resonator L1, and the inductance component is defined by the length of the strip line resonator L1.

On the other hand, when a voltage is applied to the control terminal 5, the diode D1 is on, so that the intermediate tap CT of the strip line resonator L1 is grounded via the DC blocking capacitor C3 and the diode D1. Thus, the inductance component is defined by the length between the one end of the strip line resonator L1 and the intermediate tap CT. Accordingly, the frequency becomes high as compared to that obtained when the diode D1 is off, so that the inductance component is defined by the length of the strip line resonator L1.

The frequencies at which the resonance circuit 1 resonates can be changed by turning the diode D1 on or off as described above.

However, according to the above-described conventional voltage controlled oscillator 50, when the diode D1 is turned off, the impedance at the node A (point A in FIG. 5) between the DC blocking capacitor C3 and the diode D1 becomes the open-circuit impedance on a high frequency cycle. Thus, the impedance at the node A becomes high, so that the impedance noises flow into the strip line resonator L1 via the point A and the DC blocking capacitor C3. As a result, the performance of the voltage controlled oscillator 50 is deteriorated.

### SUMMARY OF THE INVENTION

In order to overcome the problems described above, preferred embodiments of the present invention provide a voltage controlled oscillator in which deterioration of the characteristics is reliably prevented, and a communication device including such a novel voltage controlled oscillator.

In accordance with a preferred embodiment of the present invention, a voltage controlled oscillator includes a resonance circuit which resonates at a desired frequency, an oscillation circuit which oscillates at the resonance frequency of the resonance circuit, and a buffer circuit which amplifies an oscillation signal from the oscillation circuit, the resonance circuit, the oscillation circuit and the buffer circuit being connected to each other, the resonance circuit including a strip line resonator having one end thereof being grounded, a switching element connected to an intermediate tap of the strip line resonator, a DC blocking capacitor connected between the switching element and the ground, and a control terminal connected to the switching element and which applies a voltage to control the switching element.

Preferably, the switching element of the voltage controlled oscillator in accordance with this preferred embodiment of the present invention is a diode, the first terminal of the diode being connected to the intermediate tap of the strip line resonator, the second terminal of the diode being connected to the DC blocking capacitor and the control terminal, respectively.

Preferably, the switching element is a transistor, the first terminal of the transistor being connected to the intermediate tap of the strip line resonator, the second terminal thereof being connected to the DC blocking capacitor, and the third terminal thereof being connected to the control terminal.

The communication device in accordance with another preferred embodiment of the present invention includes at least one of the above-described voltage controlled oscillator.

In the voltage controlled oscillator in accordance with preferred embodiments of the present invention, one terminal of the switching element contained in the resonance circuit is connected to the intermediate tap of the strip line resonator, and the other terminal thereof is grounded via the DC blocking capacitor and is connected to the control terminal. Thus, even when the switching element is off, that is, the impedance at the node between the switching element and the control terminal is the open-circuit impedance, the node between the switching element and the control terminal is grounded on a high frequency cycle via the DC blocking capacitor. Thus, the impedance at the node between the switching element and the control terminal can be maintained at a low level.

The communication device in accordance with a preferred embodiment of the present invention includes the voltage controlled oscillator so that the susceptibility to disturbance noises is very low. Thus, communication devices having desirable communication characteristics at plural frequencies, especially at low frequencies, can be provided.

Other features, elements, characteristics and advantages of the present invention will become more apparent from the following detailed description of the preferred embodiments with reference to the attached drawings.

### BRIEF DESCRIPTION OF THE DRAWINGS

FIG. 1 is a circuit diagram of a voltage controlled oscillator according to a first preferred embodiment of the present invention;

FIG. 2 is a graph showing the output characteristics of the voltage controlled oscillator of FIG. 1;

FIG. 3 is a circuit diagram of a voltage controlled oscillator according to a second preferred embodiment of the present invention;

FIG. 4 is a block diagram of a communication device according to another preferred embodiment of the present invention; and

FIG. 5 is a circuit diagram of a conventional voltage controlled oscillator.

### DETAILED DESCRIPTION OF PREFERRED EMBODIMENTS

Hereinafter, preferred embodiments of the present invention will be described with reference to the drawings. In preferred embodiments of the present invention, the same or equivalent elements to those of the conventional example are designated by the same reference numerals, and the repeated description is omitted.

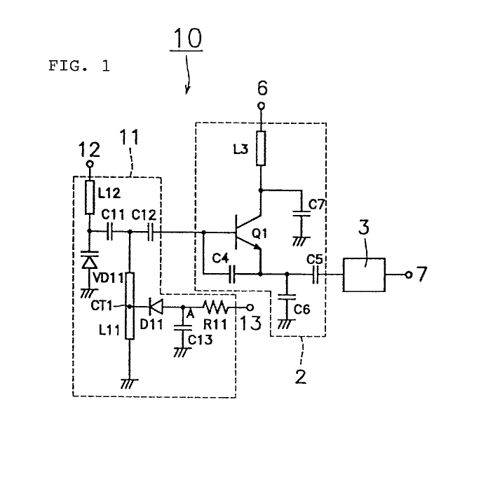

FIG. 1 is a circuit diagram of a voltage controlled oscillator according to a first preferred embodiment of the present invention. A voltage controlled oscillator 10 changes between two different frequencies to operate, and includes a resonance circuit 11, the oscillation circuit 2, and the buffer circuit 3.

The resonance circuit 11 selects one of the two different frequencies, and outputs a signal resonated at the selected frequency. The resonance circuit 11 includes a variable capacity diode VD11, a diode D1 which is a switching element, a strip line resonator L11, an inductor L12, a resistor R11, coupling capacitors C11 and C12, and a DC blocking capacitor C13.

The anode of the variable capacity diode VD11 is grounded, and the cathode is connected to a voltage-supply terminal 12 via the inductor L12. The node between the variable capacity diode VD11 and the inductor L12 is connected to the oscillation circuit 2 via the coupling capacitors C11 and C12.

One end of the strip line resonator L11 is connected to the node between the coupling capacitors C11 and C12, and the other end is grounded. An intermediate tap CT1, which is located at a position other than the ends of the strip line resonator L11, of the strip line resonator L11 is connected to the cathode of the diode D11 which is a first terminal thereof. The anode of the diode D11 which is a second terminal thereof is grounded via the DC blocking capacitor C13. Moreover, the anode of the diode D11 is connected to a control terminal 13 via the resistor R11.

The coupling capacitor C11 couples the variable capacity diode VD11 to the strip line resonator L11. The coupling capacitor C12 couples the strip line resonator L11 to the oscillation circuit 2. The oscillation circuit 2 and the buffer circuit 3 of the voltage controlled oscillator 10 preferably have the same configurations as those of the conventional voltage controlled oscillator 50 (FIG. 5), respectively.

Referring to the voltage controlled oscillator 10 configured as described above, a signal resonated by the resonance circuit 11 is input to the base of the transistor Q1 in the oscillation circuit 2, and is oscillated by the transistor Q1. The oscillation signal is amplified by the buffer circuit 3 and is output via the output terminal 7. Two different frequencies can be changed and used for oscillation by controlling the on-off of the diode D11 using a voltage applied to the control terminal 13.

In particular, when no voltage is applied to the control terminal 13, the diode D11 is off, so that the diode D11 and the DC blocking capacitor C13 are electrically separated from the strip line resonator L11, and the inductance component is defined by the length of the strip line resonator L11.

On the other hand, when a voltage is applied to the control terminal 13, the diode D11 is on, so that the intermediate tap CT1 of the strip line resonator L11 is grounded via the diode D11 and the DC blocking capacitor C13. Thus, the inductance component is defined by the length between the one end of the strip line resonator L11 and the intermediate tap CT1. Accordingly, the frequency becomes high compared to that obtained when the diode D11 is off, so that the inductance component is defined by the length of the strip line resonator L11.

The frequencies at which the resonance circuit 11 resonates can be changed by turning the diode D11 on or off as described above.

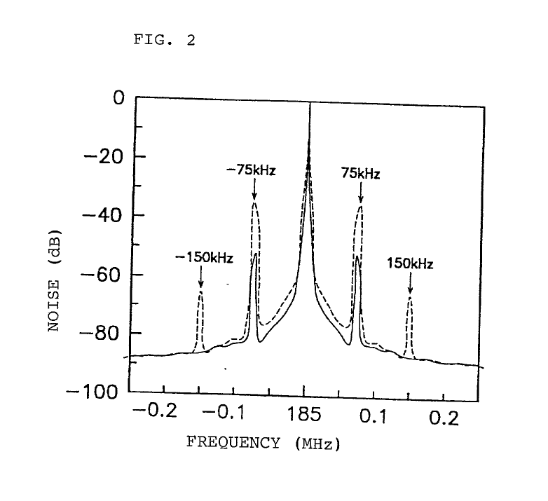

In FIG. 2, the solid line represents the output characteristic of the voltage controlled oscillator 10 of the first preferred embodiment shown in FIG. 1, and the broken line represents that of the conventional voltage controlled oscillator 50 shown in FIG. 5.

As seen in FIG. 2, the spurious waves generated at about ±75 kHz and about ±150 kHz in the voltage controlled oscillator 10 of the first preferred embodiment at an oscillation frequency of about 185 MHz are greatly reduced. This shows that the susceptibility of the voltage controlled oscillator 10 of the first preferred embodiment to disturbances noises is much less compared to that of the voltage controlled oscillator 50.

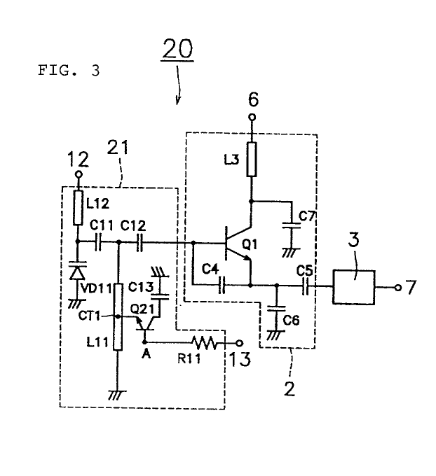

FIG. 3 is a circuit diagram of a voltage controlled oscillator according to a second preferred embodiment of the present invention. A voltage controlled oscillator 20 changes between two different frequencies to operate, and is different from the voltage controlled oscillator 10 (FIG. 1) of the first preferred embodiment in that the switching element contained in a resonance circuit 21 is a transistor Q21.

That is, the resonance circuit 21 includes the variable capacity diode VD11, the transistor Q21 that defines a switching element, the strip line resonator L11, the inductor L12, the resistor R11, the coupling capacitors C11 and C12, and the DC blocking capacitor C13.

The intermediate tap CT1, which is located at a position other than the ends in the strip line resonator L11, of the strip line resonator L11 is connected to the emitter as a first terminal of the transistor Q21. The collector as a second terminal of the transistor Q21 is grounded via the DC cut capacitor C13. Moreover, the base as a third terminal of the transistor Q21 is connected to the control terminal 13 via the resistor R11.

According to the voltage controlled oscillators 10 and 20 of the above-described preferred embodiments, the one terminal of the diode D11 or the transistor Q21 which is a switching element contained in the resonance circuit 11 or 20 is connected to the intermediate tap CT1 of the strip line resonator L11, and the other terminal of the diode D11 or the transistor Q21 is grounded via the DC blocking capacitor C13, and moreover, is connected to the control terminal 13. Accordingly, even when the diode D11 or the transistor Q21 is off, that is, the impedance at the node A (point A in FIG. 1 or 3) between the diode D11 and the control terminal 13 or between the transistor Q21 and the control terminal 13, is the open-circuit impedance, the node A is grounded on a high frequency cycle via the DC blocking capacitor C13. Thus, the impedance at the point A can be maintained at a low level.

Accordingly, disturbance noises are reliably prevented from flowing into the strip line resonator via the point A. Voltage controlled oscillators that are not affected by disturbance noises can be provided.

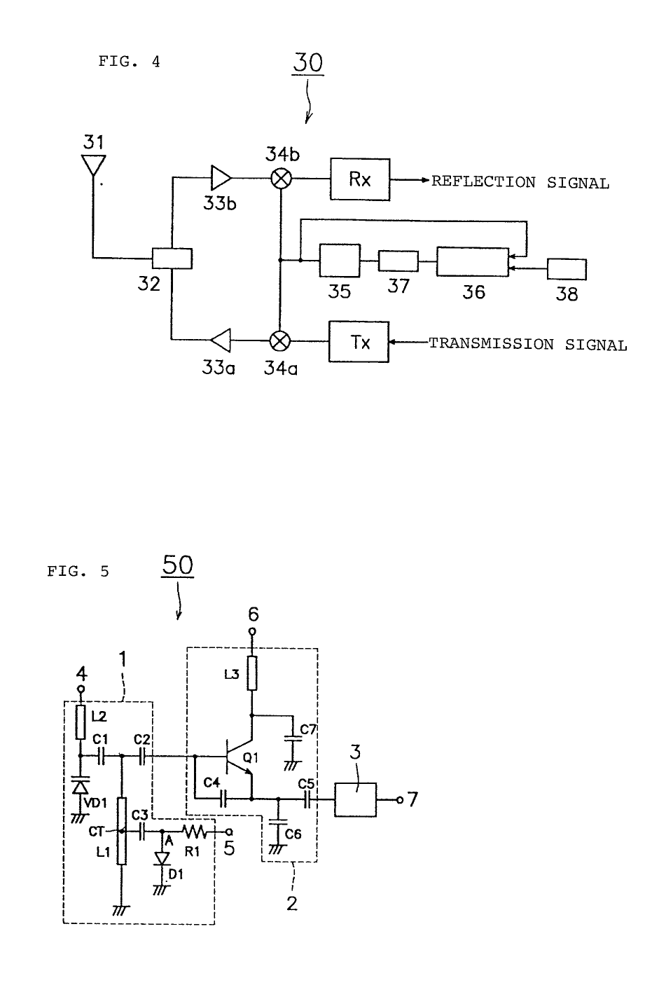

FIG. 4 is a block diagram of a communication device according to another preferred embodiment of the present invention. A communication device 30 preferably includes an antenna 31, a duplexer 32, amplification units 33a and 33b, mixing units 34a and 34b, a voltage controlled oscillator 35, a PLL control circuit 36, a low-pass filter 37, a temperature compensation crystal oscillation circuit 38, a transmission unit Tx, and a reception unit Rx.

An output signal from the voltage controlled oscillator 35 is input to the PLL control circuit 36, in which the phase is compared with that of an oscillation signal from the temperature compensation crystal oscillation circuit 38. The PLL control circuit 36 outputs a control voltage having a predetermined frequency and a predetermined phase.

The voltage controlled oscillator 35 receives the control voltage via the low-pass filter 37 at the control terminal thereof, and outputs a high frequency signal corresponding to the control voltage. The high frequency signal is applied as a local oscillation signal to the mixing units 34a and 34b, respectively.

The mixing unit 34a mixes an intermediate frequency signal output from the transmission unit Tx with the local oscillation signal to convert the signals to a transmission signal. The transmission signal is amplified in the amplification unit 33a and radiated from the antenna 31 via the duplexer 32.

A reception signal from the antenna 31 is transmitted via the duplexer 32 and amplified in the amplification unit 33b. The mixing unit 34b mixes the reception signal amplified in the amplification unit 33b with the local oscillation signal from the voltage controlled oscillator 35 to convert them to an intermediate frequency signal. The intermediate frequency signal is signal-processed in the reception unit Rx.

The voltage controlled oscillators 10 and 20 of the preferred embodiments of FIGS. 1 and 3 are used as the voltage controlled oscillators 35 in the above-described communication device 30.

The above-described communication device of the present preferred embodiment includes the voltage controlled oscillator of preferred embodiments that have little or no susceptibility to disturbance noises. Thus, communication devices having excellent communication characteristics at plural frequencies, especially, low frequencies, are provided.

The oscillation circuit and the buffer circuit, which are described as being part of the voltage controlled oscillator of the respective preferred embodiments, have a general circuit configuration, respectively. The voltage controlled oscillator of the present invention can be realized, even if the oscillation circuit and the buffer circuit have another circuit configuration, respectively.

Moreover, integration of the voltage controlled oscillator of each of the above-described preferred embodiments can be made so as to define a single unitary module.

Referring to a combination of the plural different frequencies, for example, the DCS (Digital Cellular System: 1.8 GHz band) system and the GSM (Global System for Mobile Communications: 900 MHz band) system in Europe, the PCS(Personal Communication Services: 1.9 GHz band) system and the AMPS (Advanced Mobile Phone Services: 800 MHz system in North America, and the DECT (Digital European Cordless Telephone: 1.9 GHz band) system and the GSM system, and the PHS (Personal Handy-phone System: 1.9 GHz ) system and the PDC (Personal Digital Cellular: 800 MHz band) system in Japan, and so forth may be combined, respectively.

In the voltage controlled oscillator in accordance with various preferred embodiments of the present invention, one terminal of the switching element included in the resonance circuit is connected to the intermediate tap of the strip line resonator, and the other terminal thereof is grounded via the DC blocking capacitor and is connected to the control terminal. Thus, even when the switching element is off, that is, the impedance at the node between the switching element and the control terminal becomes the open-circuit impedance, the node between the switching element and the control terminal is grounded on a high frequency cycle via the DC blocking capacitor. Thus, the impedance at the node between the switching element and the control terminal can be maintained at a low level.

Accordingly, disturbance noises can be prevented from flowing into the strip line oscillator via the node between the switching element and the control terminal. Thus, voltage controlled oscillators having little or no susceptibility to disturbance noises are provided.

The communication device in accordance with another preferred embodiment of the present invention includes the voltage controlled oscillator of other preferred embodiments having little or no susceptibility to disturbance noises. Thus, communication devices having excellent communication characteristics at plural frequencies, especially, at low frequencies, are provided.

While preferred embodiments of the invention have been described above, it is to be understood that variations and modifications will be apparent to those skilled in the art without departing the scope and spirit of the invention. The scope of the invention, therefore, is to be determined solely by the following claims.

What is claimed is:

1. A voltage controlled oscillator comprising:
a resonance circuit that resonates at a desired frequency;
an oscillation circuit that oscillates at the resonance frequency of the resonance circuit;
a buffer circuit that amplifies an oscillation signal from the oscillation circuit, the resonance circuit, the oscillation circuit and the buffer circuit being connected to each other;
the resonance circuit including a strip line resonator having one end thereof being grounded, a switching element connected to an intermediate tap of the strip line resonator, a DC blocking capacitor connected between the switching element and the ground, and a control terminal connected to the switching element and arranged to apply a voltage to control the switching element.

2. A voltage controlled oscillator according to claim 1, wherein the switching element is a diode, the first terminal of the diode being connected to the intermediate tap of the strip line resonator, the second terminal of the diode being connected to the DC blocking capacitor and the control terminal, respectively.

3. A voltage controlled oscillator according to claim 1, wherein the switching element is a transistor, the first terminal of the transistor being connected to the intermediate tap of the strip line resonator, the second terminal thereof being connected to the DC blocking capacitor, and the third terminal thereof being connected to the control terminal.

4. A voltage controlled oscillator according to claim 1, wherein the resonance circuit changes between at least two different frequencies to allow the voltage controlled oscillator to operate at the at least two different frequencies.

5. A voltage controlled oscillator according to claim 4, wherein the two different frequencies include two of a 1.8 GHz band, a 1.9 GHz band, a 900 MHz band, and a 800 MHz band.

6. A voltage controlled oscillator according to claim 1, wherein the resonance circuit selects one of two different frequencies of operation and outputs a signal resonated at the selected frequency.

7. A voltage controlled oscillator according to claim 6, wherein the two different frequencies include two of a 1.8 GHz band, a 1.9 GHz band, a 900 MHz band, and a 800 MHz band.

8. A communication device comprising the voltage controlled oscillator according to claim 1.

9. A communication device comprising the voltage controlled oscillator according to claim 2.

10. A communication device comprising the voltage controlled oscillator according to claim 3.

11. A communication device comprising the voltage controlled oscillator according to claim 4.

12. A communication device comprising the voltage controlled oscillator according to claim 5.

13. A communication device comprising the voltage controlled oscillator according to claim 6.

14. A communication device comprising the voltage controlled oscillator according to claim 7.
